(19) United States
(12) Patent Application Publication
(10) Pub. No.: US 2011/0213663 A1
(43) Pub. Date: Sep. 1, 2011

(54) SERVICE INTELLIGENCE MODULE PROGRAM PRODUCT

(75) Inventor: GEORGE E. HOFFMAN, SAN JOSE, CA (US)

(73) Assignee: CARRIER IQ, INC., MOUNTAIN VIEW, CA (US)

(21) Appl. No.: 12/762,416

(22) Filed: Apr. 19, 2010

Related U.S. Application Data
(60) Provisional application No. 61/308,483, filed on Feb. 26, 2010.

(51) Int. Cl. G06Q 30/00; H03M 7/34; G06F 17/30; G06N 5/02

(52) U.S. Cl. 705/14.58; 341/51; 707/755; 707/772; 706/48; 705/347; 707/E17.061

(57) ABSTRACT

A service intelligence module may be embodied as a system or as a method for configuring a processor. It comprises at least a metric definition, which is a computer executable rule for parsing a binary formatted log message for a metric type; and a measure factory, which configures a processor to publish attributes of a measure determined by a calculation or computation performed on a metric collected by a data collection agent. A service intelligence module further comprises an enrichment which joins two datastreams having a common dimension. Service intelligence modules may capture and analyze such domains as illustrated but not limited to: application analytics, carrier comparative quality and performance analytics, advertising audience segmentation analysis, and content copyright analytics. A computer executed method and program product comprising codes for reading recorded values from a metric package and generating measures, under control of a mobile service intelligence platform for display to a user of a domain specific analysis service. A combination of service intelligence modules may be selected and applied to a study. Each service intelligence module may have aspects for combining and organizing data along useful dimensions for analysis, and for reading pertinent metrics to transformation into measures in the form appropriate to a specific study.

A related U.S. Pat. No. 7,609,650 discloses COLLECTION OF DATA AT TARGET WIRELESS DEVICES USING DATA COLLECTION PROFILES which determines the contents of metrics packages as used in the present patent application.

### BACKGROUND

On a global basis, several competing telecommunications technologies provide alternatives for mobile or cellular telephony and broadband wireless services. In developing a general purpose analysis environment, it is necessary to segregate domain specific metrics parsing and analysis to provide manageable deliverables. Yet much infrastructure may be reusable if defined in carefully standardized interfaces. An analysis system developed with only CDMA protocols and assumptions in mind will be uneconomic to convert to a GSM/UTMS environment. With much consolidation in the industry, some companies will have to transition from one standard to another and maintain some legacy services for some period. What is needed is a way to reuse as much carrier analysis infrastructure as possible while supporting rather incompatible architectures and philosophies.

### SUMMARY OF THE INVENTION

A metric analyzer as disclosed in Pat. No. 7,609,650 comprises a Data Mart, at least one domain specific analyzer, a platform, a plurality of flows and a plurality of Service Intelligence Modules.

A service intelligence module may be embodied as a system or as a method to configure a processor. It comprises at least a metric definition, which is a computer executable rule for parsing an event record, in an embodiment a text or binary formatted log for a metric type, and a measure factory which configures a processor to publish attributes of a measure determined by a calculation or computation performed on one or more metrics collected by a data collection agent. A service intelligence module further comprises an enrichment which joins two data streams having a specified commonality, in an embodiment, a dimension. In addition a service intelligence module may have an aggregation which determines one or more characteristics of a population specific to a domain by analyzing a plurality of measures. In support of at least one of automatic generation and validation of data collection profiles, a service intelligence module may provide profile requirements specifying instructions or measurements necessary for a data collection agent to execute or to record to provide as a prerequisite to determining an attribute of a measure. To support scaling across many supported devices, a service intelligence module may include a certification test for acceptance or for regression. Service intelligence modules may capture and analyze such domains as illustrated but not limited to: application analytics, carrier comparative quality and performance analytics, advertising audience segmentation analysis, and content copyright analytics.

Each Service Intelligence Module provides the ability to read metric packages and derive at least one measure which is pertinent to a specific domain or technology. It is the centralization of domain specific derivations, transformations, and knowledge that enables Service Intelligence Modules to be generated, tested, and released asynchronously of each other and from the platform.

In a preferred embodiment, a SIM comprises a plurality of program elements which each operate on a metrics package, as defined in Pat. No. 7,609,650 Collection of data at wireless devices using data collection profiles,
when selected by a flow and invoked by a Mobile Service Intelligence Platform to produce at least one measure. The measure can be stored in a data mart. In an embodiment a measure and related attributes can be displayed to a user of an analyzer service.

A combination of service intelligence modules may be selected and applied to a study. One selection may be from among service intelligence modules related to chipsets or hardware architectures. An other selection may be from among service intelligence modules tailored to operating systems. An other selection may be from among service intelligence modules tailored to communication standards or protocols. An other selection may be from among service intelligence modules specialized to telephony or to broadband. An other selection may be from among service intelligence modules related to games, financial transactions, and medical diagnostics. Each service intelligence module may have aspects for optimizing display of results, for combining and organizing data along useful dimensions for analysis, and for reading pertinent metrics to transformation into measuress in the form appropriate to a specific study.

### BRIEF DESCRIPTION OF DRAWINGS

FIG. 1 is block diagram of a conventional server comprising a exemplary processor configured to perform instructions encoded on machine readable media.

FIG. 2 is an input-output diagram of an exemplary Service Intelligence Module. FIG. 3 is a block diagram of a system which comprises a Service Intelligence Module.

### DETAILED DISCLOSURE OF EMBODIMENTS

A Service intelligence module comprises

at least one Metric Definition which comprises computer executable rules for parsing a formatted event record such as but not limited to a binary log for one or more metric types. In an embodiment a metric definition comprises range checking tests to determine validity of the metric. In an other embodiment, a metric definition comprises constraint checking tests to determine if a metric is consistent with other metrics. In an other embodiment, a metric definition comprises a parsing configuration to convert to analog values such as time, location, signal.

In an other embodiment, a metric definition comprises a key to categorize failure types, hardware/software states, errors, arguments, text strings, queries.

A service intelligence module also comprises

at least one Measure Factory which configures a processor to publish attributes of a measure determined by a calculation performed on metrics collected by a data collection agent. In an embodiment, a measure factory comprises steps to filter metrics to be acceptable or unacceptable. In an other embodiment, a measure factory comprises thresholds that categorize or bin results. In an other embodiment, a measure factory comprises converts a binary code into text using a table, In an other embodiment, a measure factory comprises a transformation of a plurality of metrics into a plurality of attributes of measures. In an other embodiment, a measure factory comprises a transformation of a plurality of metrics to determine and categorize a transaction. In an other embodiment, a measure factory comprises a transformation of a plurality of metrics to determine a pattern. In an other embodiment, a measure factory transforms a plurality of metrics into a single measure.

In a preferred embodiment, a service intelligence module further comprises Enrichments which are steps to configure a process to transform data by effecting a join between two datastreams having some identified commonality. In an embodiment, an enrichment recognizes a pattern related to a start recorded in a first package and an end recorded in a second package. In an other embodiment, an enrichment recognizes a pattern related to at least two events recorded in attributes of a plurality of measures. In an other embodiment, an enrichment interpolates a value between values recorded in a plurality of packages. In an other embodiment, an enrichment recognizes a pattern determined by interaction among two independent data collection agents. In an other embodiment, an enrichment determines a third measure by operating on a plurality of first measures and a plurality of second measures. In an other embodiment, an enrichment estimates a third location based on a first recorded location and a second recorded location. In an other embodiment, an enrichment comprises an inference based on a pattern of attributes of measures recorded by a data collection agent over a period.

In an other embodiment a service intelligence further comprises Aggregations. An aggregation comprises instructions to configure a processor to determine a characteristic of a population specific to a domain determined by analyzing a plurality of measures. In an other embodiment, an aggregation comprises instructions to determine a statistical value of at least one attribute of a plurality of measures. In an other embodiment, an aggregation comprises a domain—specific analysis determined by examining attributes from a plurality of sources. In an other embodiment, an aggregation comprises an accumulation of the result of a selected enrichment.

In an embodiment a service intelligence module further comprises Profile requirements. Profile requirement comprise instructions to specify instructions or measurements necessary for a data collection agent to execute or record to provide as a prerequisite to determining an attribute of a measure. In an embodiment profile requirements comprises elements of a program to be compiled into a profile for installation at a mobile device to record data for a study dependent on availability of attributes of a measure. In an embodiment profile requirements specify classes of data that must be included in a data collection profile in order to operate a service intelligence module to generate an attribute of a measure.

In an embodiment, a service intelligence module further comprises one or more Certification Tests. A Certification test comprises:
a profile or profile requirements,
a simulator control to provide a signal channel environment, and
an acceptance test of values to be read from a package to pass certification.

In an embodiment, a service intelligence module further comprises Application Analytics comprising instruction to configure a processor to
read application identification from a mobile device,
record the start and the stop of application execution,
record user selections and interactions within the application,
read location, orientation, or accelerations, and
determine user behavior, preferences, or difficulties.

In an embodiment a service intelligence module further comprises Carrier Comparative Quality and Performance Analytics comprising instructions to configure a processor to:
read signal quality and performance metrics for a plurality of carriers,
compare a first carrier signal with a contractual threshold, and
dynamically reselect a carrier for each location according to price, quality and performance.

In an embodiment a service intelligence module further comprises Advertising Segmentation Analytics comprising instructions to configure a processor to:
read content selection,
read location data,
read application activity, and
determine presentation/deselection of advertising messages.

In an embodiment a service intelligence module further comprises Content Copyright Analytics comprising instructions to configure a processor to:
read a binary coded content copyright holder signature recorded on a display device,
read a start time for display of content,
read an identification code for a display device, and
aggregate the display time during a period for a plurality of content copyright holders.

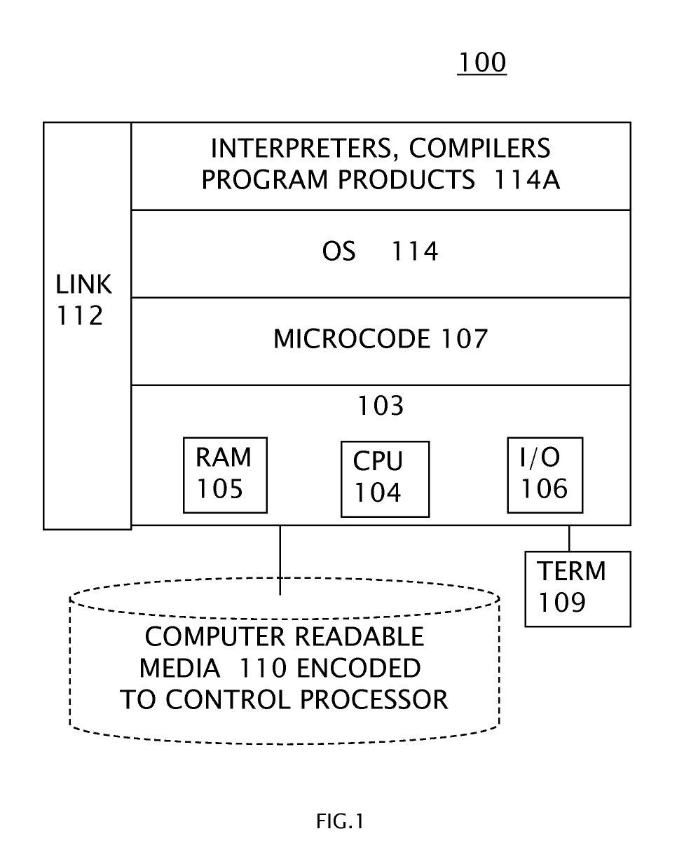

Referring now to the drawings, FIG. 1 illustrates a non-limiting exemplary conventional server known in the art comprising hardware and software configured to execute instructions and communicate to attached networks and input output devices. A processor, circuit, or programmable logic configured by instructions in a computer readable device as discussed below provides means for enabling any of the functions claims.

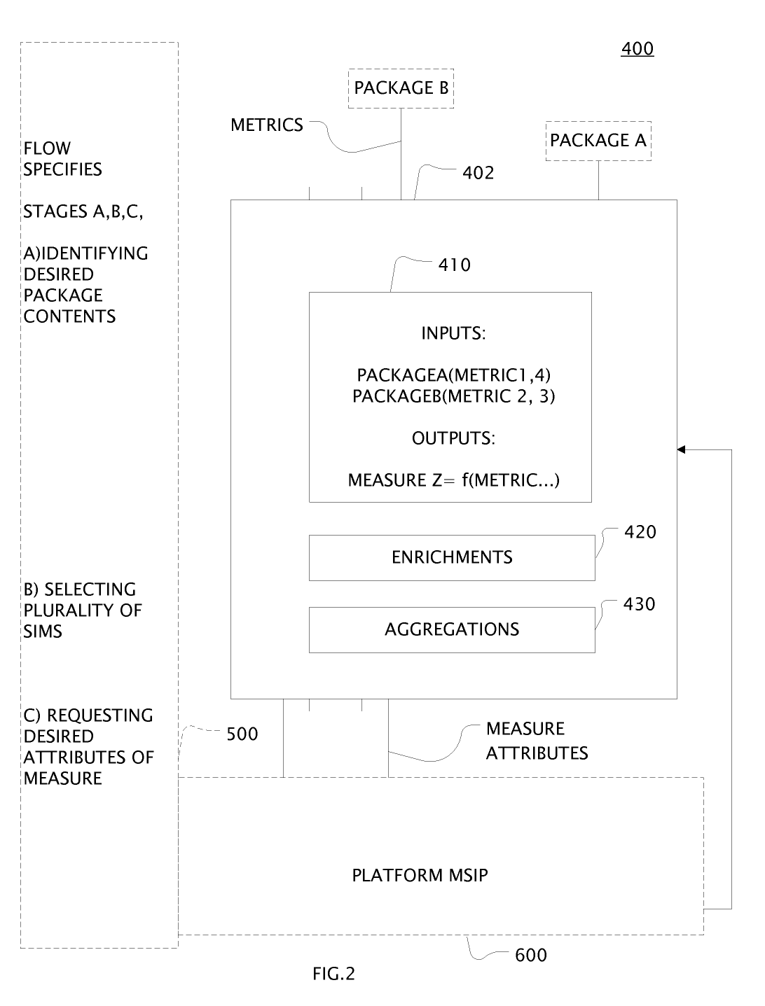

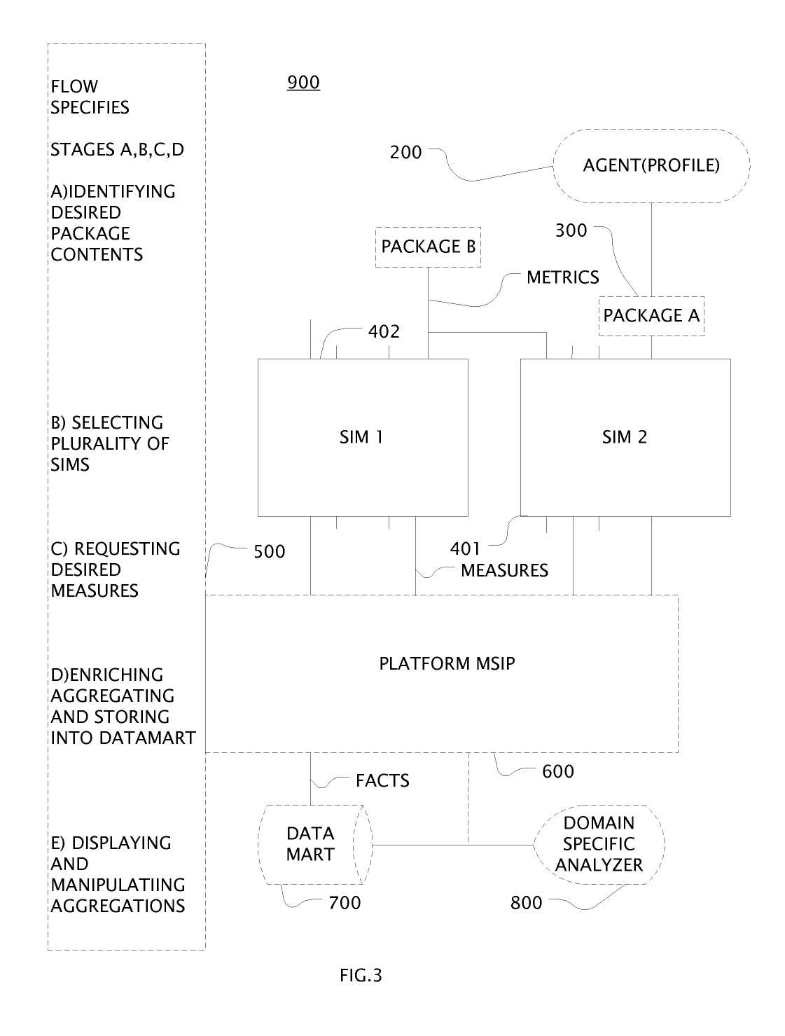

Referring now to FIG. 2, a non-limiting exemplary SIM 402 is shown as producing two measures under the control of the platform MSIP 600. The requirement of producing each of the two measures is obtained from the flow 500 and provided to the SIM. It may be that one measure is derived from metrics contained in Package A and the other measure is derived from metrics contained in Package B. It may be that both measures can be obtained from Package B alone but only one can be derived from Package A alone. In an embodiment, a SIM reads only one package at a time but derives as many required measures as it can from a single package.

SIMs in an embodiment, contain enrichments, and expose “virtual measure factories” which conceptually just produce measures like a measure factory, but which in actuality run potentially multiple measure factories and then send those primitive measures through some enrichments. In an embodiment, a virtual measure factory comprises a pre-assembled set of enrichments which looks like a single measure factory and can be used like one. In an embodiment, an enrichment comprises a pre-assembled set of measure factories which looks like a single measure factory and can be used like one. In an embodiment, an enrichment circuit comprises a processor adapted by computer executable instructions to read data from packages, compute measures, and combine measures into new measures. SIMs are designed to support this, because the particular way that measures must be combined may be highly domain-specific, and it is the SIM's purpose to encapsulate domain intelligence. Each SIM has the ability to read a plurality of metrics from a package but will only read those necessary in order to generate measures as described by the flow, including which attributes should be computed. Each SIM has the ability to derive a plurality of measures (and attributes) from metrics contained within a package but will only derive those requested by the flow via the platform MSIP or by a domain specific analyzer user via the platform MSIP.

A SIM comprises at least one measure factory 410 comprising
a flow directive receiver,
a metric reader, and
a measure determinator.

In an embodiment, a flow engages an enrichment which comprise a generic component that the flow customizes. In an embodiment of the invention, a flow engages program elements within a SIM which comprise an enrichment circuit. In an embodiment of the invention, a flow engages an aggregation circuit. In an embodiment, a circuit is a processor configured by computer executed instructions.

In an embodiment, a SIM further comprises an enriching circuit and is called by a flow. In an embodiment, a flow 500 makes use of at least one enrichment circuit 420 provided in a SIM. An enrichment determines an event or fact from analyzing a plurality of measures which may emanate from metrics recorded at different sources or different times.

In an embodiment, a SIM further comprises an aggregation circuit and is called by a flow. In an embodiment, a flow 500 makes use of at least one aggregation circuit 430 provided in a SIM. An aggregation provides a statistic such as an average over a plurality of measures in a related population.

Referring now to FIG. 3, an overview of a service quality analysis system 900 is provided to show the relationship of one or more SIMs to other parts. An agent 200 residing on a service quality client that stores and forwards data according to the profile it has been provided to generate a Package A 300 which contains those metrics specified in the profile. The metrics in Package A are parsed by the Platform MSIP and read into SIM 2 401 which in an embodiment comprises a measure factory capable of deriving at least one measure. Note that SIM 1 402 comprises at least one measure factory which is configured to produce two measures from Package B. Package B is shown as containing metrics which can be operated on by both SIM 1 and SIM 2. In an embodiment a SIM is a module which contains some number of measure factories, as well as other things (metric parser definitions, enrichments, etc.). In an embodiment, a SIM is configured to read a single package and produce at least one measure. In an embodiment, measure factories are allowed to produce no measures for a given input package (for example, if the package doesn't have anything of interest). SIMs are controlled by a Flow 500 through the MSIP platform 600. In an embodiment multiple measures are aggregated or manipulated within a flow to create facts. Ideally, most enrichments and aggregations occur using resources and services available to all flows as APIs provided by the platform MSIP. The measures derived from a package by each SIM are combined into facts and stored into the Data Mart 700 for retrieval and analysis in a Domain Specific Analyzer 800 along with the Package IDs and SIMs used to create the fact.

In an embodiment, the “Domain Specific Analyzer” is contained in the SIM. In an embodiment, the “Domain Specific Analyzer” is implemented primarily using components provided by the SIM. The SIM comprises artifacts required to understand a particular domain, non-limiting exemplary artifacts including display or UI components unique to that domain. In a preferred embodiment for configuration control purposes, changes to enhance or correct handling of domain specific subject matter may be accomplished within a single SIM. To handle very complex domains, knowledge may be distributed into a hierarchy of related SIMs. A first SIM may refer to a second SIM to handle a specialized sub-class of the domain or an extension of a domain. Divergent overloading of the semantics of metrics by different conditions may be handled by such partitioning. In an embodiment all artifacts required to understand a particular domain are provided in a unitary SIM.

Drilling down through aggregated data, a user of the Domain Specific Analyzer may select one or more facts for detailed viewing. In an interactive basis the SIM may be invoked to operate on a specific package to generate presentation attributes which are not generally required by a flow for economical reasons. In an embodiment, a SIM comprises an enrichment which takes multiple measures at a time as input.

In a preferred embodiment, a flow directive receiver of a measure factory within a SIM receives parameters specified in a flow and provided to the SIM by the Mobile Service Intelligence Platform which determines
identity and characteristics of a package to be processed,
which metrics in the package to extract,
at least one of the measure types declared by the SIM to be determined from the metrics.

A measure determinator reads the data from one package stored by the metric reader and manipulates the data recorded at one agent. The measure factory expects a particular contract to be fulfilled by the profile with regard to the package format, and it can use any package which satisfies this contract.

In an embodiment, a SIM comprises an enriching circuit which reads at least two measures derived from two packages sent by one agent.

In an embodiment, a SIM comprises an enriching circuit which reads a plurality of measures, each derived from a package sent by a plurality of agents.

In an embodiment, a SIM comprises an aggregating circuit which reads at least two measures derived from two packages sent by one agent.

In an embodiment, a SIM comprises an aggregating circuit which reads a plurality of measures, each derived from a package sent by a plurality of agents.

In an embodiment, a SIM comprises a display control circuit for domain specific analysis by a user.

In an embodiment, a SIM comprises the definition of each metric it uses.

In an embodiment, a metric definition in a SIM is encrypted. In an embodiment, a metric definition is digitally signed. In an embodiment, all of the constituent parts of a SIM are digitally signed. In an embodiment, all of the constituent parts of a SIM are encrypted.

In an embodiment, a metric definition in a SIM is digitally signed.

In a preferred embodiment, the present invention comprises a computer executed method for processing a metrics package file, comprising:

receiving a flow directive comprising parameters specified in a flow and provided to a service intelligence module by a Service Intelligence Platform which determines
identity and characteristics of a package to be processed,
which metrics in the package to extract, and

at least one of the measure types declared by the SIM to be determined from the metrics.

In a preferred embodiment, the method further includes:

operating on a plurality of metrics from one package stored by the metric reader and manipulating the data recorded at one agent between a start time and a stop time in combination with stored values, thresholds, and patterns to determine a measure requested in the flow.

In a preferred embodiment, the method further includes:

controlling a measure store control to store the results from a measure determinator and also storing information about the origin of the metrics used to create the measure and information about the package providing the metrics.

The present invention is embodied by a computer readable medium containing program elements operable to instruct a computer system to operate on a computer-readable metrics package data file, where the metrics package data file is recorded at a mobile device according to a data collection profile,
the program elements comprising instructions for:
   receiving flow directives from a service intelligence platform,
   reading at least one metric recorded by a mobile service client, and
   determining a measure by operating on the values of at least one metric.

In a preferred embodiment, the program elements recognize an event of interest to a study by determining a plurality of measures by operating on the values provided in one metric package.

In a preferred embodiment, the program elements create a plurality of display attributes of a metrics package by
determining the identity of the metrics package from metadata embedded in a measure generated by the metrics package, and
retrieving the metrics package, operating on it, and generating presentation attributes.

The present invention comprises a computer program product in a computer readable medium for use in a data processing system for filtering incoming data from an external computer network, the computer program product comprising:
instructions for receiving a metrics package of data recorded at a mobile agent according to a collection profile; and
instructions for determining at least one measure within a domain of technology, of the service quality of the applications and telecommunication operation at a mobile device.

In a preferred embodiment, the computer program product further comprises instructions for checking a digital signature in a metrics package against an authentication code within the service intelligence module. In a preferred embodiment a SIM comprises authentication credentials which are available to validate a SIM to a platform and to validate selected packages to the certain SIM.

In a preferred embodiment, the computer program product further comprises a signature whereby the MSIP validates a service intelligence module before reading and executing its instructions.

In an embodiment, a SIM comprises a pattern or rule-base to recognize a user transaction from a set of metrics.

In an embodiment, a SIM comprises an event stream pattern recognition circuit to identify a sequence of states.

In an embodiment, a SIM comprises a pattern recognition circuit to identify display of content/playing of music/a sequence of movements.

In an embodiment, a SIM comprises user application fuzzy logic measures of multidimensional patterns.

An other embodiment of the invention comprises a method for operating a processor to transform at least one metrics package into at least one attribute of a measure or at least one fact for storage, analysis, and display comprising the following steps:

checking a collection profile associated with a metrics package to determine if the service intelligence module is related to the metrics contained by the package;

reading data from the package; and

transforming a metrics value in the package into an attribute of a fact. A service intelligence module comprises at least one measure factory. A measure factory may operate on m metrics to generate n attributes which may be attributes of p measures. In an embodiment the integers m, n, and p are equal. In an embodiment m is less than n or p. In an embodiment n is greater than p. A measure factory is stateless and is thus laterally scalable across a plurality of processors operating independently on a plurality of packages. Each instance of a measure factory does not share a resource with an other instance of the same measure factory. The architecture of service intelligence modules may be described as a shared nothing system which results in horizontal scalability.

An other embodiment of the invention comprises a method for operating a processor to transform a plurality of metrics packages into a selected attribute of a fact for storage, analysis and display comprising the following steps:

checking a collection profile associated with a plurality of metrics package to determine if the service intelligence module is related to the metrics contained by the packages;

reading data from the packages; and

transforming a metrics value in a first package in combination with a metrics value an a second package into an attribute of a fact.

An other embodiment of the invention comprises a system comprising a processor configured to transform a single metrics package into a fact for storage, analysis, and display comprising the following steps:

checking a collection profile associated with a metrics package to determine if the service intelligence module is related to the metrics contained by the package;

reading data from the package; and

transforming a metrics value in the package into an attribute of a fact.

An other embodiment of the invention comprises a system comprising a processor configured to transform a metrics package into a selected attribute of a measure for storage, analysis and display comprising the following steps:

checking a collection profile to determine if the service intelligence module is related to the metrics contained by the packages;

reading data from the packages;

validating data as within desired range, format, syntax; and

transforming a metric value into an attribute of a fact. In an embodiment the system reads at least one reference file providing information about the metrics.

In an embodiment, the system further comprises means for controlling display of measures comprising rich logical information about attributes of measures.

In an embodiment, the system further comprises means for associating package identifiers and service intelligence module identifiers with each measure stored into a data mart whereby a user can drill into a fact to find out more detail or analyze in an unanticipated way.

In an embodiment, the system further comprises

means for tracing copyright ownership of content displayed on the device.

In an embodiment, the system further comprises

means for comparing quality of service of a plurality of carriers.

In an embodiment, the system further comprises

means for grouping device identifiers of mobile device users who frequently traverse a certain geographical area.

In an embodiment, the system further comprises

means for grouping device identifiers of mobile device users who have a higher probability of occupying a certain geographical area.

In an embodiment, the system further comprises

means for reading acceleration, orientation, and inertial data from a package.

In an embodiment, the system further comprises

means for reading chemical, temperature, and biological data from a package.

### CONCLUSION

As indicated herein, embodiments of the present invention may be implemented in connection with a special purpose or general purpose telecommunications device, including wireless and wireline telephones, other wireless communication devices, or special purpose or general purpose computers as illustrated in FIG. 1 that are adapted to have comparable telecommunications capabilities. Embodiments within the scope of the present invention also include computer-readable media 110 for carrying or having computer-executable instructions or electronic content structures stored thereon, and these terms are defined to extend to any such media or instructions that are used with telecommunications devices.

By way of example such computer-readable media can comprise RAM, ROM, flash memory, EEPROM, CD-ROM or other optical disk storage, magnetic disk storage or other magnetic storage devices, or any other medium which can be used to carry or store desired program code in the form of computer-executable instructions or electronic content structures and which can be accessed by a general purpose or special purpose computer, or other computing device.

When information is transferred or provided over a network or another communications connection (either hardwired, wireless, or a combination of hardwired or wireless) to a computer or computing device, the computer or computing device properly views the connection as a computer-readable medium. Thus, any such a connection is properly termed a computer-readable medium. Combinations of the above should also be included within the scope of computer-readable media. Computer-executable instructions comprise, for example, instructions and content which cause a general purpose computer, special purpose computer, special purpose processing device or computing device to perform a certain function or group of functions.

Although not required, aspects of the invention have been described herein in the general context of computer-executable instructions, such as program modules, being executed by computers 100 in network environments. A example of a computer in a horizontally scalable system is illustrated in FIG. 1 comprising a server 100. Said server comprises a processor 103 configured by microcode 107, an operating system 114, and in embodiments interpreters, compilers, and program products 114A. Such a system is coupled to other servers through a network link 112, and to a local or remote terminal 109. A conventional processor 103 comprises random access memory 105, a central processing unit 104 and an input output circuit 106. Generally, program modules include routines, programs, objects, components, and content structures that perform particular tasks or implement particular abstract content types. Computer-executable instructions, associated content structures, and program modules represent examples of program code for executing aspects of the methods disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A Service intelligence module program product comprising
at least one Metric Definition, the metric definition comprising computer executable rules for parsing a binary formatted log message for a metric type; and
at least one Measure Factory, the measure factory comprising instructions to configure a processor to publish attributes of a measure determined by a calculation performed on a metric collected by a data collection agent.

2. The service intelligence module of 1 further comprising at least one Enrichment, the enrichment comprising a join between two datastreams having a common dimension.

3. The service intelligence module of claim 2 wherein a metric definition comprises range checking tests to determine validity of the metric.

4. The service intelligence module of claim 2 wherein a metric definition comprises constraint checking tests to determine if a metric is consistent with other metrics.

5. The service intelligence module of claim 2 wherein a metric definition comprises a parsing configuration to convert to analog values.

6. The service intelligence module of claim 2 wherein a metric definition comprises a key to text strings.

7. The service intelligence module of claim 2 wherein a measure factory comprises filters which determine metrics to be acceptable or unacceptable.

8. The service intelligence module of claim 2 wherein a measure factory comprises thresholds that categorize results into bins.

9. The service intelligence module of claim 2 wherein a measure factory comprises converts a binary code into text using a table.

10. The service intelligence module of claim 2 wherein a measure factory comprises a transformation of a plurality of metrics into a plurality of attributes of measures.

11. The service intelligence module of claim 2 wherein an enrichment recognizes a pattern related to a start recorded in a first package and an end recorded in a second package.

12. The service intelligence module of claim 2 wherein an enrichment recognizes a pattern related to at least two events recorded in attributes of a plurality of measures.

13. The service intelligence module of claim 2 wherein an enrichment interpolates a value between values recorded in a plurality of packages.

14. The service intelligence module of claim 2 wherein an enrichment recognizes a pattern determined by interaction among two independent data collection agents.

15. The service intelligence module of claim 2 wherein an enrichment determines a third measure by operating on a plurality of first measures and a plurality of second measures.

16. The service intelligence module of claim 2 wherein an enrichment estimates a third location based on a first recorded location and a second recorded location.

17. The service intelligence module of claim 2 wherein an enrichment comprises an inference based on a pattern of attributes of measures recorded by a data collection agent over a period.

18. The service intelligence module of claim 2 further comprising at least one Aggregation, the aggregation comprising determination of a characteristic of a population specific to a domain determined by analyzing a plurality of measures.

19. The service intelligence module of claim 18 wherein an aggregation is a statistical value of at least one attribute of a plurality of measures.

20. The service intelligence module of claim 18 wherein an aggregation is a domain-specific analysis determined by examining attributes from a plurality of sources.

21. The service intelligence module of claim 18 wherein an aggregation is an accumulation of the result of a selected enrichment.

22. The service intelligence module of 2 further comprising at least one Profile requirement, the profile requirement comprising specifying instructions or measurements necessary for a data collection agent to execute or record to provide as a prerequisite to determining an attribute of a measure.

23. The service intelligence module of 22 wherein a profile requirement comprises elements of a program to be compiled into a profile for installation at a mobile device to record data for a study dependent on availability of attributes of a measure.

24. The service intelligence module of 22 wherein a profile requirement comprises what must be included in a data collection profile in order to operate a sim to generate an attribute of a measure.

25. The service intelligence module of 2 further comprising at least one Certification Test, the certification test comprising an acceptance test of values to be read from a package to pass certification.

26. The service intelligence module of 25 wherein said certification test further comprises a testbed of data to collect, and a simulator control to provide a signal channel environment.

27. The service intelligence module of claim 2 further comprising Application Analytics, the application analytics comprising instruction to adapt a processor to
read application identification from a mobile device,
read location, orientation, or accelerations, and
determine user preferences, errors, and demographics.

28. The service intelligence module of claim 2 further comprising Carrier Comparative Quality and Performance Analytics, the carrier comparative quality and performance analytics comprising instructions to configure a processor to:
read signal quality and performance metrics for a plurality of carriers,
compare a first carrier signal with a contractual threshold, and
dynamically reselect a carrier for each location according to price, quality and performance.

29. The service intelligence module of claim 2 further comprising Advertising Segmentation Analytics, the advertising segmentation analytics comprising instruction to configure a processor to
read content selection,
read location data,
read application activity, and
determine presentation/deselection of advertising messages.

30. The service intelligence module of claim 2 further comprising Content Copyright Analytics, the content copyright analytics comprising instruction to configure a processor to
read a binary coded content copyright holder signature recorded on a display device,
read a start time for display of content,
read an identification code for a display device, and
aggregate the display time during a period for a plurality of content copyright holders.

31. A computer executed method for processing a metrics package file, comprising:
receiving a flow directive comprising parameters specified in a flow and provided to a service intelligence module by a Service Intelligence Platform which determines
identity and characteristics of a package to be processed,
which metrics in the package to extract,
at least one of the measure types declared by the SIM to be determined from the metrics.

32. A method as in claim 31, where the method further includes:
operating on a plurality of metrics from one package stored by the metric reader and manipulating the data recorded at one agent in combination with stored values, thresholds, and patterns to determine a measure requested in the flow.

33. A computer readable medium containing program elements operable to instruct a computer system to operate on a computer-readable metrics package data file, where the metrics package data file is recorded at a mobile device according to a data collection profile,
the program elements comprising instructions for:
receiving flow directives from a service intelligence platform,
reading at least one metric recorded by a mobile service client, and
determining a measure by operating on the values of at least one metric.

34. The computer readable medium of claim 33, wherein the program elements recognize an event of interest to a study by
determining a plurality of measures by operating on the values provided in at least one metric package.

35. The computer readable medium of claim 33, wherein the program elements create a plurality of display attributes of a metrics package by
determining the identity of the metrics package and SIM(s) employed from metadata embedded in a measure generated by the metrics package, and
retrieving the metrics package, operating on it, and generating presentation attributes.

36. A computer program product in a computer readable medium for use in a data processing system for filtering incoming data from an external computer network, the computer program product comprising:
instructions for receiving a metrics package of data recorded at a mobile agent according to a collection profile; and
instructions for determining at least one measure within a domain of technology, of the service quality of the applications and telecommunication operation at a mobile device.

37. The computer program product according to claim 36, further comprising
instructions for checking a digital signature in a metrics package against an authentication code within the service intelligence module.

38. The computer program product according to claim 36, further comprising
an authentication code for authenticating itself to a service intelligence platform performing an authorization check.

39. A method for operating a processor to transform a single metrics package into a measures for storage, analysis, and display comprising the following steps:
checking a collection profile associated with a metrics package to determine if the service intelligence module is related to the metrics contained by the package;
reading metrics values from the package; and
transforming a metrics value in the package into an attribute of a measure.

40. A method for operating a processor to transform a plurality of first measures into a second measure for storage, analysis and display comprising the following steps:
reading attributes of said first measures; and
transforming an attribute of said first measures into a second measure.

41. A system comprising a processor configured to transform a single metrics package into a measure for storage, analysis, and display comprising means for adapting the processor to perform the following:
check a collection profile associated with a metrics package to determine if the service intelligence module is related to the metrics contained by the package;
read data from the package; and
transform a metrics value in the package into an attribute of a measure.

42. A system comprising a processor configured to transform a plurality of first measures into a second measure for storage, analysis and display comprising means for:
reading data from the first measures;
validating data as within desired range, format, syntax; and
transforming data from the first measures into a second measure.

43. The system of claim 42 further comprising
means for controlling display of measures comprising rich logical information about attributes of measures.

44. The system of claim 42 further comprising
means for associating package identifiers and service intelligence module identifiers with each measures stored into a data mart whereby a user can drill into a measures to find out more detail or analyze in an unanticipated way.

45. The system of claim 42 further comprising
means for tracing copyright ownership of content displayed on the device.

46. The system of claim 42 further comprising
means for comparing quality of service of a plurality of carriers.

47. The system of claim 42 further comprising
means for grouping device identifiers of mobile device users who frequently traverse a certain geographical area.

48. The system of claim 42 further comprising
means for grouping device identifiers of mobile device users who have a higher probability of occupying a certain geographical area.

49. The system of claim 42 further comprising
means for reading acceleration, orientation, and inertial data from a package.

50. The system of claim 42 further comprising
means for reading chemical, temperature, and biological data from a package.
